(19) United States
(12) Patent Application Publication
(10) Pub. No.: US 2023/0291173 A1
(43) Pub. Date: Sep. 14, 2023

(54) LASER

(71) Applicant: HISENSE LASER DISPLAY CO., LTD., Shandong (CN)

(72) Inventors: Zinan ZHOU, Shandong (CN); Youliang TIAN, Shandong (CN); Xin ZHANG, Shandong (CN); Yunchen LU, Shandong (CN); Jianjun LI, Shandong (CN); Xintuan TIAN, Shandong (CN); Qian SHAO, Shandong (CN)

(21) Appl. No.: 18/321,257

(22) Filed: May 22, 2023

Related U.S. Application Data
(63) Continuation of application No. PCT/CN2021/130892, filed on Nov. 16, 2021.

(30) Foreign Application Priority Data
Nov. 25, 2020 (CN) 202022785523.5
Feb. 7, 2021 (CN) 202120345209.7

(51) Int. Cl. H01S 5/0233; H01S 5/40; H01S 5/024; H01S 5/02315

(52) U.S. Cl. CPC H01S 5/0233; H01S 5/4025; H01S 5/02469; H01S 5/02315

(57) ABSTRACT

Provided is a laser. The laser includes: a base plate, an annular side wall, a plurality of conductive pins, a plurality of light-emitting chips, and a plurality of conductive wires; wherein the side wall and the plurality of light-emitting chips are disposed on the base plate, the side wall surrounds the plurality of light-emitting chips, the plurality of conductive pins are extended through the side wall and are affixed into the side wall, and sides, distal from the base plate, of portions of the plurality of conductive pins surrounded by the side wall include planar regions, wherein the planar region of each of the plurality of conductive pins is connected to the light-emitting chip via the conductive wire.

### CROSS-REFERENCE TO RELATED APPLICATIONS

This application is a continuation application of International Application No. PCT/CN2021/130892, filed on Nov. 16, 2021, which claims priority to Chinese Patent Application No. 202022785523.5, filed on Nov. 25, 2020 and entitled “LASER,” and Chinese Patent Application No. 202120345209.7, filed on Feb. 7, 2021 and entitled “LASER,” the disclosures of which are herein incorporated by references in their entireties.

### TECHNICAL FIELD

The present disclosure relates to the field of photoelectric technologies, and in particular, relates to a laser.

### BACKGROUND OF THE INVENTION

With the development of photoelectric technologies, and lasers have been widely used.

### SUMMARY OF THE INVENTION

Embodiments of the present disclosure provide a laser. The laser includes a base plate, an annular side wall, a plurality of conductive pins, a plurality of light-emitting chips, and a plurality of conductive wires.

The side wall and the plurality of light-emitting chips are disposed on the base plate, the side wall surrounds the plurality of light-emitting chips, the plurality of conductive pins are extended through the side wall and are affixed into the side wall, and sides, distal from the base plate, of portions of the plurality of conductive pins surrounded by the side wall include planar regions, wherein the planar region of each of the plurality of conductive pins is connected to the light-emitting chip via the conductive wire.

Embodiments of the present disclosure further provide a laser. The laser includes a base plate, an annular side wall, a plurality of conductive pins, a plurality of light-emitting chips, a plurality of conductive wires, and a plurality of supports.

The side wall and the plurality of light-emitting chips are disposed on the base plate, the side wall surrounds the plurality of light-emitting chips, the plurality of conductive pins are extended through the side wall and are affixed into the side wall, the plurality of supports are affixed on the base plate, each of the plurality of supports corresponds to one of the plurality of supports, and a first conductive face of each of the plurality of supports is connected to a wiring region of the corresponding conductive pin and a target electrode of the light-emitting chip via the conductive wires.

### BRIEF DESCRIPTION OF DRAWINGS

For clearer description of the technical solutions in the embodiments of the present disclosure, the following briefly describes the accompanying drawings required for describing the embodiments. Apparently, the accompanying drawings in the following description show merely some embodiments of the present disclosure, and those of ordinary skill in the art may still derive other drawings from these accompanying drawings without any creative efforts.

FIG. 1 is a schematic structural diagram of a laser in some practices;

FIG. 2 is a schematic structural diagram of a laser according to some embodiments of the present disclosure;

FIG. 3 is a schematic structural diagram of another laser according to some embodiments of the present disclosure;

FIG. 4 is a schematic structural diagram of another laser according to some embodiments of the present disclosure;

FIG. 5 is a schematic structural diagram of another laser according to some embodiments of the present disclosure;

FIG. 6 is a schematic structural diagram of a laser in some practices;

FIG. 7 is a schematic structural diagram of a laser according to some embodiments of the present disclosure;

FIG. 8 is a schematic structural diagram of another laser according to some embodiments of the present disclosure;

FIG. 9 is a schematic structural diagram of another laser according to some embodiments of the present disclosure;

FIG. 10 is a schematic structural diagram of another laser according to some embodiments of the present disclosure;

FIG. 11 is a schematic structural diagram of a support according to some embodiments of the present disclosure; and

FIG. 12 is a schematic structural diagram of another laser according to some embodiments of the present disclosure.

### DETAILED DESCRIPTION OF THE INVENTION

To make the objectives, technical solutions, and advantages of the present disclosure clearer, the embodiments of the present disclosure are further described in detail hereinafter with reference to the accompanying drawings.

With the development of photoelectric technologies, lasers are being more and more widely used. For example, the laser is used in welding, cutting, and laser projection, and miniaturization of the lasers are more and more desired. In packaging chips of the laser, a structure of the laser is subject to poor reliability, and thus stricter requirements are being imposed on the reliability and manufacturing effect of the laser. The embodiments of the present disclosure provide a laser, which improves the manufacturing effect of the laser.

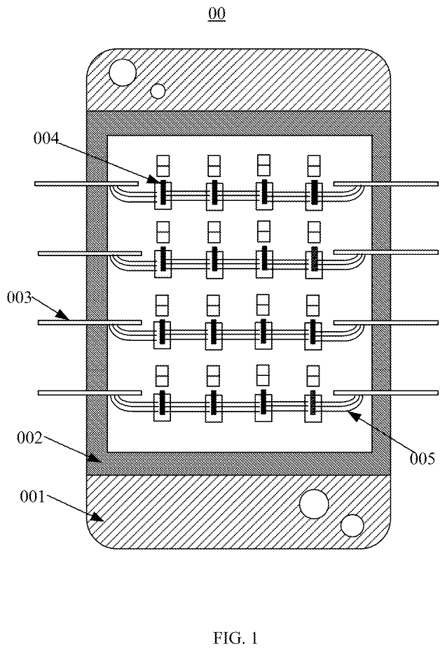

As shown in FIG. 1, in some practices, the laser 00 includes a base plate 001, an annular side wall 002, a plurality of cylindrical conductive pins 003, a plurality of light-emitting chips 004, and a plurality of gold wires 005. The side wall 002 and the plurality of light-emitting chips 004 are affixed on the base plate 001, the side wall 002 surrounds the plurality of light-emitting chips 004, and the plurality of conductive pins 003 are extended through the side wall 002 and are affixed into the side wall 002. Portions, outside the side wall 002, of the plurality of conductive pins 003 are connected to an external power supply, portions, surrounded by the side wall 002, of the plurality of conductive pins 003 are connected to one end of the gold wire 005, and the other end of the gold wire 005 is connected to the light-emitting chip 004. The external power supply supplies a current to the light-emitting chip 004 via the conductive pin 003 and the gold wire 005, such that the light-emitting chip 004 is excited to emit laser light to achieve luminescence of the laser.

In manufacturing the laser, a wiring tool is required to apply a force to the conductive pin 003 to affix the gold wire 005. However, the wiring tool is prone to sliding in applying the force to the conductive pin 003, such that an affixation effect of the gold wire on the conductive pin 003 is poor, and thus the manufacturing effect of the laser is poor.

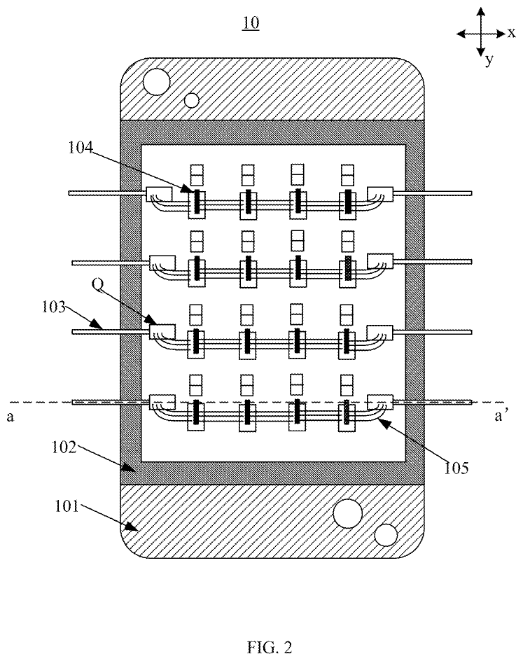

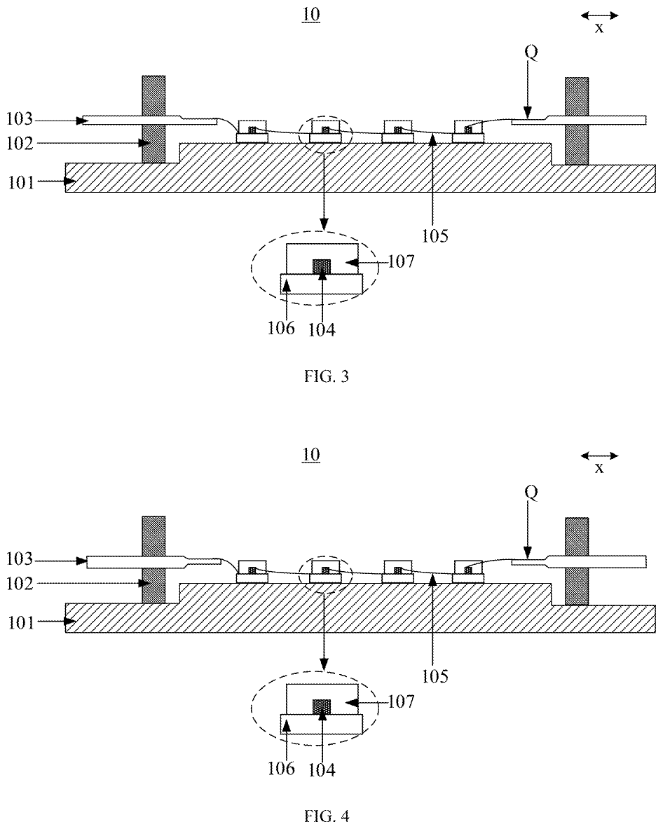

FIG. 2 is a schematic structural diagram of a laser according to some embodiments of the present disclosure. FIG. 3 is a schematic structural diagram of another laser according to some embodiments of the present disclosure. FIG. 3 illustrates a section a-a′ of the laser shown in FIG. 2, and FIG. 2 illustrates a top view of the laser shown in FIG. 3. As shown in FIG. 2 and FIG. 3, the laser 10 includes a base plate 101, an annular side wall 102, a plurality of conductive pins 103, a plurality of light-emitting chips 104, and a plurality of conductive wires 105.

The side wall 102 and the plurality of light-emitting chips 104 are affixed on the base plate 101, the conductive pins 103 are extended through the side wall 102 and are affixed into the side wall 102, and the side wall 102 surrounds the plurality of light-emitting chips 104 and one ends of the conductive pins 103. A structure defined by the side wall 102 and the base plate 101 is referred to as a housing, a space defined by the side wall 102 and the base plate 101 and surrounded by the side wall 102 is an accommodation space of the housing, and one end of the conductive pin 103 is extended into the accommodation space. The conductive pin 103 is in a strip shape, a side, distal from the base plate 101, of a portion of the conductive pin 103 surrounded by the side wall 102 includes a planar region Q, and the planar region Q of each conductive pin 103 is connected to the light-emitting chip 104 via the conductive wire 105.

For example, in the embodiments of the present disclosure, the plurality of conductive pins 103 are respectively affixed on two opposite sides of the side wall 102, and the plurality of light-emitting chips 104 in the laser are arranged on the base plate 101 in an array. That is, the plurality of light-emitting chips 104 are arranged in a plurality of rows and a plurality of columns. The two opposite sides of the side wall 102 are two opposite sides of the side wall 102 in a row direction of the light-emitting chips 104, and two ends of each row of the light-emitting chips 104 are disposed with the conductive pin 103. The light-emitting chips 104 in each row in the laser are cascaded, for example, each light-emitting chip in each row of the light-emitting chips 104 is connected to adjacent light-emitting chip via the conductive wire 105. Two light-emitting chips 104, at two ends, in each row of the light-emitting chips 104 are respectively connected to two conductive pins 103 on the side wall via the conductive wire 105. For example, one end of the conductive wire 105 is affixed in the planar region Q of the conductive pin 103, and the other end of the conductive wire 105 is affixed on an electrode of the light-emitting chip 104. The two conductive pins 103 are respectively connected to a positive terminal and a negative terminal of the external power supply, such that the external power supply supplies the current to light-emitting chip via the conductive pin, and then the light-emitting chips 104 of the row are excited to emit laser light.

It should be noted that FIG. 2 and FIG. 3 are illustrated by taking the laser including eight conductive pins 103, four conductive pins 103 and the other four conductive pins 103 being respectively affixed into the two opposite sides of the side wall 102, and the laser including 20 light-emitting chips arranged in four rows and five columns as an example. In some embodiments, a number of the conductive pins in the laser is twice of a number of rows of the light-emitting chips, and the laser includes 14 light-emitting chips arranged in two rows and seven columns, or 12 light-emitting chips arranged in three rows and four columns, or other number of light-emitting chips arranged in other arrangement, which is not limited in the embodiments of the present disclosure.

In some embodiments, the laser in the embodiments of the present disclosure is a laser of a single color. In the case that the laser of the single color is a red laser, as a size of a light-emitting chips for emitting red laser light is greater than a size of a light-emitting chip for emitting blue laser light and a size of a light-emitting chip for emitting green laser light, the conductive pin is flattened. In the case that the laser of the single color is a blue laser or a green laser, a size of a light-emitting chip is less, and thus an area of a heat sink is less. Thus, a support is required to connect the heat sink to the conductive pin. In this case, the conductive pin is flattened or not flattened.

In some embodiments, the laser in the embodiments of the present disclosure is a laser of multiple colors, and the light-emitting chips in the laser include light-emitting chips for emitting red laser light, light-emitting chips for emitting green laser light, and light-emitting chips for emitting blue laser light. The light-emitting chips for emitting the laser light of the same color in the laser are cascaded. For example, all the light-emitting chips in the laser are used to emit laser light of the same color and are cascaded, and the conductive pins in the laser merely include one positive pin and one negative pin.

In the embodiments of the present disclosure, the conductive wire is affixed on the conductive pin and the electrode of the light-emitting chip by a ball bonding technique. In bonding the conductive wire by the ball bonding technique, an end of the conductive wire is melted by a wiring tool, the melted end is pressed on an object to be connected, and the wiring tool supplies ultrasonic to achieve the affixation of the conductive wire to the object to be connected. In some embodiments, the conductive wire 105 is a gold wire, and the affixation process of the conductive wire and the conductive pin is also referred to as a gold wire bonding process. In the embodiments of the present disclosure, the object to be connected is the planar region of the conductive pin, the wiring tool is not prone to sliding when in contact with the planar region, and the wiring tool securely presses the melted end of the conductive wire on the planar region, such that the affixation effect of the conductive wire on the conductive pin is ensured, and the manufacturing yield of the laser is improved.

In addition, each conductive pin is generally connected to the light-emitting chip via a plurality of conductive wires. In the case that welding points of the plurality of conductive wires are in a plane, the affixation effect of the plurality of conductive wires is great. In the embodiments of the present disclosure, the plurality of conductive wires are affixed on the planar region of the conductive pin, and the welding points of the plurality of conductive wires are within the planar region, such that the welding points of the plurality of conductive wires are in a same plane, and the affixation effect of the plurality of conductive wires is great.

In summary, in the embodiments of the present disclosure, the side, distal from the base plate, of the portion of the conductive pin in the laser surrounded by the side wall includes the planar region, and the conductive wire can connect the planar region to the light-emitting chip. In affixing the conductive wire on the conductive pin by the wiring tool, the wiring tool securely applies the force on the planar region of the conductive pin, such that the affixation effect of the conductive wire on the conductive pin is improved, and the manufacturing yield of the laser is optimized.

In the embodiments of the present disclosure, the conductive pin is connected to the light-emitting chip via a plurality of conductive wires. For example, a number of the plurality of conductive wires ranges from 2 to 10, and a diameter of each conductive wire ranges from 25 μm to 50 μm. In some embodiments, the number of the conductive wires is associated with a size of the conductive wire and a current required by the luminous of the light-emitting chip. Illustratively, the current required by the luminous of the light-emitting chip is 3 amperes, and the diameter of the conductive wire ranges from 25 μm to 50 μm. In the case that the diameter of the conductive wire is 25 μm, the number of the conductive wires connecting a first conductive pin and a first support is four or five. In the case that the diameter of the conductive wire is 50 μm, the number of the conductive wires connecting a first conductive pin and a first support is at least 12.

In some embodiments, a length of the planar region Q in an extension direction (the x direction in FIG. 2 or FIG. 3) of the conductive pin 103 ranges from 2 mm to 3 mm, and a length of the planar region in a direction (the y direction) perpendicular to the extension direction of the conductive pin ranges from 1 mm to 2 mm. In some embodiments, a boundary of the planar region Q on the side, distal from the base plate 101, of the conductive pin 103 is in a rectangular shape, and a length direction of the rectangle is parallel to the extension direction of the conductive pin 103. In the case that the planar region is in the rectangle shape, a length of the rectangle ranges from 2 mm to 3 mm, and a width of the rectangle ranges from 1 mm to 2 mm. In some embodiments, the boundary of the planar region Q is in a diamond shape, a triangular shape, an oval shape, a circular shape, a hexagonal shape, or other shapes, which is not limited in the embodiments of the present disclosure. A size of the planar region in a shape other than the rectangle in the x direction or the y direction still meets the above length range.

In some embodiments, a total length of the conductive pin ranges from 8 mm to 10 mm in the embodiments of the present disclosure. In the extension direction of the conductive pin 103, a length of the portion of the conductive pin 103 surrounded by the side wall 102 ranges from 3 mm to 3.5 mm. The conductive pin is made of an iron-nickel alloy, and a surface of the conductive pin is coated with a metal layer.

In the embodiments of the present disclosure, referring to FIG. 2 and FIG. 3, the planar region Q in the conductive pin 103 is disposed at an end, distal from the side wall 102, of the portion of the conductive pin 103 surrounded by the side wall 102. In some embodiments, in the case that the portion of the conductive pin 103 surrounded by the side wall 102 is longer, the planar region is disposed at an end, proximal to the side wall 102, of the portion of the conductive pin 103 surrounded by the side wall 102. It should be noted that a plurality of holes are disposed in the side wall of the laser, and each conductive pin is extended into a space surrounded by the side wall via a hole and is affixed into the side wall by solder (for example, glass cement) in the hole. As a center region of the conductive pin is within the hole in the side wall, the conductive pin is affixed into the side wall through the center region, the conductive pin is equivalent to a lever landed at the hole of the side wall, and the hole is equivalent to a pivot of the lever. The more proximal the position of the lever to the pivot, the greater the force acceptable at the position. In the case that a force is applied on the position, the conductive pin is not prone to sliding. As the force is applied on a welding position of each conductive wire on the conductive pin in affixing the conductive wire and the conductive pin, the proximity of the planar region to the side wall can ensure that the conductive pin is reliably affixed into the side wall even if the force is applied on the planar region in affixing the conductive wire in the planar region in the embodiments of the present disclosure, such that the position of the conductive pin is prevented from shifting, and the conductive pin is ensured to operate normally.

In the embodiments of the present disclosure, a surface, proximal to the base plate 102, of the conductive pin 103 is in a curved shape bending towards the base plate 101. For example, a position of a side face of a cylinder conductive strip is polished or milled, such that the position of the side face of the conductive strip changes from a curved face to a plane, and thus the conductive pin including the planar region Q in the embodiments of the present disclosure is acquired. In some embodiments, another portion of the conductive pin 103 is in a cylindrical shape, and an orthogonal projection of the another portion on the base plate 101 is disposed beyond an orthogonal projection of the planar region Q on the base plate. That is, the another portion is a portion of the conductive pin other than the portion of the planar region Q. In some embodiments, a diameter of a bottom face of the cylindrical another portion ranges from 0.6 mm to 0.8 mm, and the diameter of the bottom face is less than the width of the rectangular planar region.

In some embodiments, FIG. 4 is a schematic structural diagram of another laser according to some embodiments of the present disclosure. As shown in FIG. 4, the side, proximal to the base plate 101, of the portion of the conductive pin 103 surrounded by the side wall 102 includes the planar region. The planar region can refer to the related description of the planar region on the side, distal from the base plate 101, of the conductive pin, which is not repeated herein. In the case that both the side, proximal to the base plate, of the conductive pin and the side, distal from the base plate, of the conductive pin include the planar region, orthogonal projections of the two planar regions on the base plate are at least overlapped, or are coincided. In this case, an end of the cylinder conductive strip is squeezed by a squeezing tool to flatten the end of the conductive strip, such that the conductive pin including two planar regions is acquired.

Referring to FIG. 2 and FIG. 3, the laser 10 in the embodiments of the present disclosure further includes a plurality of heat sinks 106 and a plurality of reflective prisms 107. The plurality of heat sinks 106 are in one-to-one correspondence with the plurality of light-emitting chips 104, the plurality of reflective prisms 107 are also in one-to-one correspondence with the plurality of light-emitting chips 104, each light-emitting chip 104 is affixed on the base plate 101 via the corresponding heat sink 106, and each reflective prism 107 is disposed on a light-emitting side of the corresponding light-emitting chip 104. FIG. 5 is a schematic structural diagram of another laser according to some embodiments of the present disclosure. As shown in FIG. 5, the laser 10 further includes a seal frame 109, a transparent seal layer 110, and a collimator set 111. An outer edge of the seal frame 109 is affixed on a surface of the side wall 102 distal from the base plate 101, a side of an inner edge of the seal frame 109 distal from the base plate 101 is affixed on the transparent seal layer 110, and the collimator set 111 is disposed on a side of the seal frame 109 distal from the base plate 101. The collimator set 111 includes a plurality of collimating lenses T, and the plurality of collimating lenses T are in one-to-one correspondence with the plurality of light-emitting chips 104. Each light-emitting chip 104 emits the laser light to the corresponding reflective prism 107, the laser light travels through the transparent seal layer 110 upon being reflected by the reflective prism 107 and then directs to the corresponding collimating lens T, and then the laser light is transmitted upon being collimated by the collimating lens T, such that the laser emits the laser light.

In the embodiments of the present disclosure, the housing is made of copper, for example, oxygen-free copper, the transparent seal layer is made of glass, and a seal cover plate is made of a stainless steel. It should be noted that a heat transfer coefficient of copper is great, and the housing is made of copper in the embodiments of the present disclosure, such that the heat generated by the operation of the light-emitting chip on the base plate of the housing can be quickly transferred through the housing and then be quickly dissipated, and the damage on the light-emitting chip caused by heat accumulation is avoided. In some embodiments, the housing is made of one or more of aluminum, aluminum nitride, and silicon carbide. In the embodiments of the present disclosure, the seal cover plate may be made of other Kovar materials, for example, an iron nickel cobalt alloy or other alloys. The transparent seal layer may be made of other transparent materials with great reliability, for example, a resin material and the like.

In the embodiments of the present disclosure, in assembling the laser, an annular solder structure (for example, an annular glass bead) is disposed in the hole in the side wall of the housing, and the conductive pin is extended through the solder structure and the hole of the solder structure. It should be noted that in the embodiments of the present disclosure, a size of the another portion of the conductive pin other than the planar region is less than a size of the hole, and a width of the planar region is greater than or less than the size of the hole. In the case that the width of the planar region is greater than the size of the hole, the another portion of the conductive pin is extended outside the side wall through the hole from an interior of the housing. In the case that the width of the planar region is less than the size of the hole, the another portion of the conductive pin is extended outside the side wall through the hole from an interior of the side wall, or the another portion of the conductive pin is extended inside the side wall through the hole from an exterior of the side wall. The interior of the side wall herein refers to a region surrounded by the side wall, and the exterior of the side wall herein refers to a region not surrounded by the side wall.

Then, the side wall is placed on a bottom face of the base plate, an annular silver copper solder is placed between the base plate and the side wall, structures of the base plate, the side wall, and the conductive pin are placed in a high temperature furnace for seal sinter, and the base plate, the side wall, the conductive pin, and the solder are an integrated structure upon the seal sinter and curing, such that air tightness at the hole of the side wall is achieved. The transparent seal layer and the seal frame are affixed, for example, an edge of the transparent seal layer is attached to an inner edge of the seal frame, such that a seal assembly is acquired. Then, a combined member of the light-emitting chip and the heat sink and the reflective prism are welded on the base plate, and the gold wire is disposed between the planar region of the conductive pin and the light-emitting chip, and between the electrodes of the cascaded light-emitting chip by a wiring device. Then, the seal assembly is welded on the side wall by a parallel sealing welding technology, the collimator set is affixed on a side, distal from the base plate, of the seal assembly, and the assembling of laser is completed.

It should be noted that the above assembling process is merely an illustrative process in the embodiments of the present disclosure, the welding process in the process can be replaced by other process, and the order of the process can be adeptly adjusted, which are not limited in the embodiments of the present disclosure. The above embodiments of the present disclosure are illustrated by taking the base plate and the side wall of the housing being assembled as two separate structures as an example. In some embodiments, the base plate and the side wall are of an integrated structure. As such, wrinkles of the base plate caused by the different coefficients of thermal expansion of the base plate and the side wall in high temperature welding are avoided, such that the flatness of the base plate is ensured, the reliability of disposing the light-emitting chip on the base plate is ensured, emission of the light emitted by the light-emitting chip at a predetermined light-emitting angle is ensured, and the luminous effect of the laser is improved.

In summary, in the embodiments of the present disclosure, the side, distal from the base plate, of the portion of the conductive pin in the laser surrounded by the side wall includes the planar region, and the conductive wire can connect the planar region to the light-emitting chip. In affixing the conductive wire on the conductive pin by the wiring tool, the wiring tool securely applies the force on the planar region of the conductive pin, such that the affixation effect of the conductive wire on the conductive pin is improved, and the manufacturing yield of the laser is optimized.

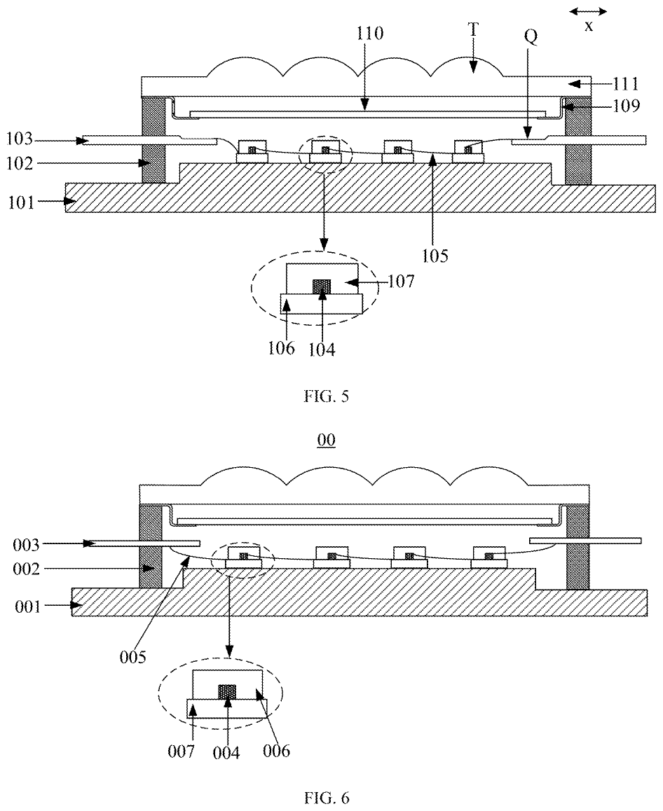

As shown in FIG. 6, in some practices, the laser 00 includes a base plate 001, an annular side wall 002, a plurality of conductive pins 003, a plurality of light-emitting chips 004, a plurality of heat sinks 005, a plurality of reflective prisms 006, and a plurality of gold wires 008. The side wall 002, the plurality of heat sinks 005, and the plurality of reflective prisms 006 are affixed on the base plate 001, each light-emitting chip 004 is affixed on one heat sink 005, and the side wall 002 surrounds the plurality of light-emitting chips 004, the plurality of heat sinks 005, and the plurality of reflective prisms 006. The plurality of conductive pins 003 are extended through two opposite sides of the side wall 002 and are affixed on the side wall 002. The portion of the conductive pin 003 surrounded by the side wall 002 is connected to the electrode of the corresponding light-emitting chip 004 via the gold wire 008, the portion of the conductive pin 003 beyond the side wall 002 is connected to the external power supply, and the external power supply supplies the current to light-emitting chip 004 through the conductive pin 003 and the gold wire 008, such that the light-emitting chips 004 are excited to emit laser light. The laser light emitted by the light-emitting chips 004 is directed to the reflective prism 006, and is then directed to a direction away from the base plate 001 upon being reflected by the reflective prism 006, such that the laser emits laser light.

However, the following case exists. As a difference in height between the conductive pin 003 and the electrode of the light-emitting chip 004 is great in some practices, a longer gold wire 008 is required to connect the conductive pin 003 and the electrode of the light-emitting chip 004, and a maximum acceptable tensile force of the gold wire is positively correlated with the difference in height between two objects connected by the gold wire and the length of the gold wire, the gold wire is prone to breaking in some practices, the reliability of the gold wire is less, and thus the reliability of the laser is less.

The following embodiments of the present disclosure are another improved technical solution based on the above embodiments, and are used to further improve the reliability of the laser.

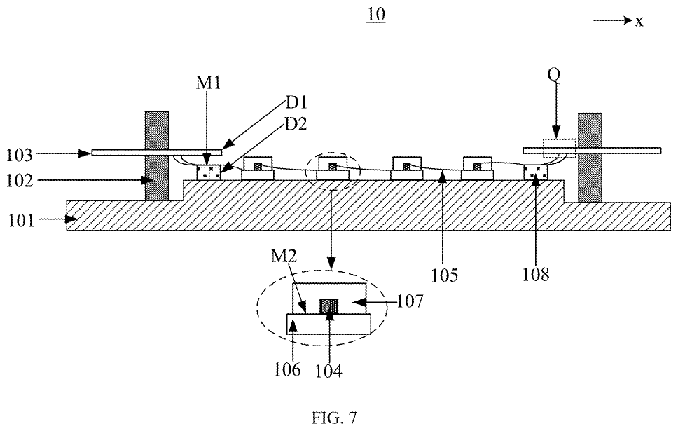

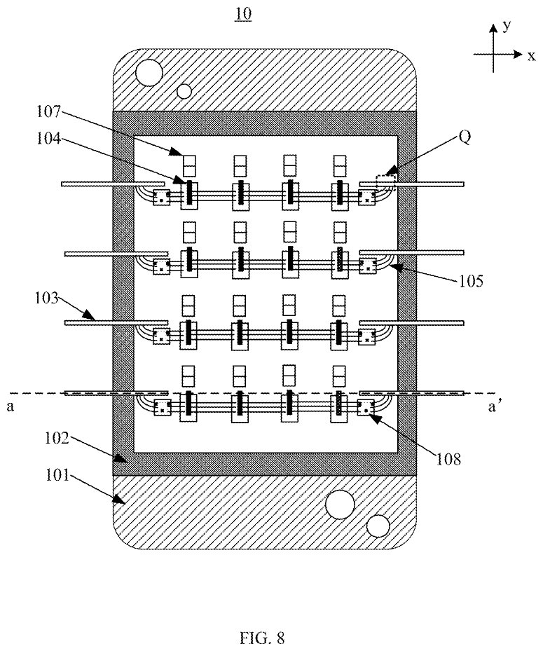

FIG. 7 is a schematic structural diagram of a laser according to some embodiments of the present disclosure. FIG. 8 is a schematic structural diagram of another laser according to some embodiments of the present disclosure. FIG. 8 illustrates a top view of the laser shown in FIG. 7, and FIG. 7 illustrates a section a-a′ of the laser shown in FIG. 8. As shown in FIG. 7 and FIG. 8, the laser 10 includes a base plate 101, an annular side wall 102, a plurality of light-emitting chips 104, a plurality of conductive pins 103, a plurality of supports 108, and a plurality of conductive wires 105.

The side wall 102, the plurality of light-emitting chips 104, and the plurality of supports 108 are disposed on the base plate 101, the conductive pin 103 is extended through the side wall 102 and are affixed into the side wall 102, and the side wall 102 surrounds the plurality of light-emitting chips 104, the plurality of supports 108, and an end of the conductive pin 103. For example, the side wall 102 is in an annular shape, a structure composed of the side wall 102, the base plate 101, and the conductive pin 103 is referred to as a housing, a space defined by the side wall 102 and the base plate 101 and surrounded by the side wall 102 is an accommodation space of the housing, and an end of the conductive pin 103 is extended into the accommodation space.

Each of the plurality of conductive pins 103 corresponds to one of the plurality of supports 108, a first conductive face M1 of each of the supports 108 is connected to a wiring region Q of the corresponding conductive pin 103 and a target electrode of the light-emitting chip 104 via the conductive wires, and the first conductive face M1 of the support 108 is a surface, distal from the base plate 101, of the support 108. For example, a first conductive pin 103 corresponds to a first support 108 in the laser, and the first conductive pin 103 is connected to a first light-emitting chip 104 through the first support 108. For example, the first conductive face M1 of the first support 108 is connected to a wiring region Q of the first conductive pin 103 and a target electrode of the first light-emitting chip 104 via the conductive wires. The first conductive pin 103 is any conductive pin 103 in the laser, and each conductive pin in the laser may be the first conductive pin.

In an extension direction (the x direction in FIG. 7 and FIG. 8) of the first conductive pin 103, the first support 108 is disposed between the wiring region Q of the first conductive pin 103 and the first light-emitting chip 104. A distance between the first conductive face M1 of the first support 108 and the base plate 101 is greater than a distance between the target electrode of the first light-emitting chip 104 and the base plate 101, and is less than a distance between the wiring region Q of the first conductive pin 103 and the base plate 101. That is, a height of the wiring region Q of the first conductive pin 103 relative to the base plate 101, a height of the first conductive face M1 of the first support 108 relative to the base plate 101, and a height of a target electrode of the first light-emitting chip 104 relative to the base plate 101 are sequentially decreased. In some embodiments, a maximum distance between the target electrode of the light-emitting chip 104 and the base plate 101 is less than 0.3 mm, the distance between the wiring region of the conductive pin 103 and the base plate 101 is greater than 0.5 mm, and the distance between the first conductive face M1 of the support 108 and the base plate 101 ranges from 0.3 mm to 0.5 mm. For example, the distance between the first conductive face M1 and the base plate 101 ranges from 0.3 mm to 0.4 mm. In some embodiments, the distance between the first conductive face M1 and the base plate 101 ranges from 0.39 mm to 0.41 mm.

In some embodiments, in the extension direction of the first conductive pin 103, the first support 108 being disposed between the wiring region Q of the first conductive pin 103 and the first light-emitting chip 104 means that in the extension direction of the first conductive pin 103, the first support 108 is disposed between two ends, distal from each other, of the wiring region Q and the first light-emitting chip 104. That is, an orthogonal projection of the first support is disposed between orthogonal projections of the two ends distal from each other on a reference face. The two ends distal from each other include an end, distal from the first light-emitting chip 104, of the wiring region Q and an end, distal from the first conductive pin 103, of the first light-emitting chip 104, and the reference face is perpendicular to the base plate and is parallel to the extension direction of the first conductive pin 103.

In the embodiments of the present disclosure, as the first support 108 is disposed between the first conductive pin and the first light-emitting chip, and the height of the first conductive face of the first support is between the height of the wiring region of the first conductive pin and the height of the target electrode of the first light-emitting chip, the distance between the wiring region and the first conductive face and the distance between the first conductive face and the target electrode are less than the distance between the wiring region of the first conductive pin and the target electrode of the first light-emitting chip, and a difference in height between the wiring region and the first conductive face and a difference in height between the first conductive face and the target electrode are less than a difference in height between the wiring region and the target electrode. Furthermore, compared with the technical solution of directly connecting the first conductive pin to the target electrode of the first light-emitting chip via the conductive wire in some practices, in the technical solution of connecting the wiring region of the first conductive pin to the first support via the conductive wire and connecting the first support to the target electrode of the first light-emitting chip via the conductive wire in the embodiments of the present disclosure, the length of each conductive wire is shorter, and the difference in height of two objects connected by each conductive wire is less. As a maximum acceptable tensile force of the conductive wire is positively correlated with the difference in height between two objects connected by the conductive wire and the length of the conductive wire, the maximum acceptable tensile force of the conductive wire in the laser is great in the embodiments of the present disclosure, the reliability of the conductive wire is great, and thus the reliability of the laser is great.

In summary, in the laser in the embodiments of the present disclosure, the electric connection of the conductive pin and the target electrode of the light-emitting chip is changed over through the support. The support is disposed between the conductive pin and the light-emitting chip, and a height of the support is between the height of the wiring region of the conductive pin and the height of the target electrode of the light-emitting chip. Thus, the conductive wire connecting the conductive pin and the support is shorter, the conductive wire connecting the support and the target electrode of the light-emitting chip is shorter, and the difference in height of two objects connected by each conductive wire is less. Thus, the reliability of the conductive wire is great, and thus the reliability of the laser is improved.

In some embodiments, the laser includes a base plate 101, a side wall 102, a plurality of light-emitting chips 104, a plurality of conductive pins 103, a plurality of supports 108, and a plurality of conductive wires 105.

Sides, distal from the base plate 101, of portions of the plurality of conductive pins 103 surrounded by the side wall 102 include planar regions Q. The planar region Q of each of the plurality of conductive pins 103 is connected to the light-emitting chip 104 via the conductive wire.

In some embodiments, in the case that the laser in the embodiments of the present disclosure is a laser of a single color, that is, all light-emitting chips emit laser light of a same color, all light-emitting chips of each row can be cascaded. For example, as shown in FIG. 7, the light-emitting chips are arranged in rows and columns, two conductive pins including one positive pin and one negative pin are disposed in each row, and two supports are disposed. That is, a number of the supports is twice of a number of the rows.

In some embodiments, in the case that the laser in the embodiments of the present disclosure is a laser of three colors, the light-emitting chips for emitting laser light of three colors are respectively disposed on one row, but not limited to one row. For example, referring to the arrangement shown in FIG. 7, the light-emitting chips are arranged as two rows of light-emitting chips for emitting red laser light, one row of light-emitting chips for emitting blue laser light, and one row of light-emitting chips for emitting green laser light. In this case, two conductive pins including one positive pin and one negative pin are disposed in each row, two supports are disposed in each row, and a number of the supports is twice of a number of the rows. Alternatively, the light-emitting chips are arranged as one row of light-emitting chips for emitting laser light of one color, and one row of light-emitting chips for emitting laser light of the other two colors. In this case, the light-emitting chips for emitting laser light of various colors share one positive pin, and the light-emitting chips for emitting laser light of the same color share at least one negative pin (that is, a R negative pin, a G negative pin, and a B negative pin). Thus, at least one support is required to connect the light-emitting chips for emitting laser light of the same color to the positive pin, and one support is required to connect the light-emitting chips for emitting laser light of the same color to the corresponding negative pin. That is, at least six supports are required. In actual practices, a number of the supports is greater than six due to a length of a support wire.

In the laser in the embodiments of the present disclosure, the conductive wire 105 is affixed on the conductive pin 103, the support 108, and the light-emitting chip 104 by the ball bonding technique. In bonding the conductive wire by the ball bonding technology, an end of the conductive wire is melted by a bonding tool, the melted end is pressed on an object to be connected to achieve the affixation of the conductive wire to the object to be connected. For example, the object to be connected is the conductive pin, the first conductive face of the support, and the target electrode of the light-emitting chip. In some embodiments, the conductive wire 105 is a gold wire.

In the embodiments of the present disclosure, the wiring region Q in the conductive pin 103 is a region, proximal to the side wall 102, of the conductive pin 103. That is, the wiring region Q in the conductive pin 103 is more proximal to the side wall 102 than another region of the conductive pin 103. It should be noted that a plurality of openings are disposed in the side wall, and each conductive pin is extended into a space surrounded by the side wall via the opening and is affixed into the side wall by solder in the hole. As a center region of the conductive pin is within the opening in the side wall, the conductive pin is affixed into the side wall through the center region, the conductive pin is equivalent to a lever landed at the opening of the side wall, and the opening is equivalent to a pivot of the lever. The more proximal the position of the lever to the pivot, the greater the force acceptable at the position. The position is not prone to sliding when a force is applied on the position. As the force is applied on a welding position of each conductive wire on the conductive pin in affixing the conductive wire and the conductive pin, the proximity of the wiring region to the side wall can ensure that the conductive pin is reliably affixed into the side wall even if the force is applied on the wiring region in affixing the conductive wire in the planar region in the embodiments of the present disclosure, such that the position of the conductive pin is avoided shifting, and the conductive pin is ensured to operate normally.

In some embodiments of the present disclosure, in the extension direction of the first conductive pin 103, a distance between an end D1, proximal to the first light-emitting chip 104, of the first conductive pin 103 and an end D2, proximal to the first light-emitting chip 104, of the first support 108 is less than a distance threshold. That is, the distance between the end D1 of the first conductive pin 103 and the end D2 of the first support 108 is less. In some embodiments, in the extension direction of the first conductive pin 103, the distance between the first support 108 and the first light-emitting chip 104 is greater than or equal to the distance between the first conductive pin 103 and the first light-emitting chip 104. That is, the end, proximal to the first light-emitting chip 104, of the first conductive pin 103 is disposed between the first support 108 and the first light-emitting chip 104 in the extension direction. Alternatively, the end, proximal to the first light-emitting chip, of the first support is disposed between the first conductive pin 103 and the first light-emitting chip, which is not limited in the embodiments of the present disclosure. As such, compared with the laser in some practices, the end, proximal to the first light-emitting chip, of the first support in the laser in the embodiments of the present disclosure does not exceed or slightly exceeds the first conductive pin, and thus the support is directly disposed based on the size and structure arrangement of the current laser without increasing the space between the first conductive pin and the first light-emitting chip, such that the setting of the structures of the laser is compact, and a volume of the laser is less.

In the embodiments of the present disclosure, the first conductive pin is connected to the first support via a plurality of conductive wires, and the first support is connected to the first light-emitting chip via a plurality of conductive wires, and a number of the conductive wires connecting the first conductive pin and the first support is equal to a number of the conductive wires connecting the first support to the first light-emitting chip. In some embodiments, ends of the plurality of conductive wires connected to the first conductive pin are sequentially affixed on a wiring region of the first conductive pin in the extension direction of the first conductive pin. It should be noted that the number of the conductive wires is associated with a size of the conductive wire and a current required by the luminous of the light-emitting chip. Illustratively, the current required by the luminous of the light-emitting chip is 3 amperes, and the diameter of the conductive wire ranges from 25 μm to 50 μm. In the case that the diameter of the conductive wire is 25 μm, the number of the conductive wires connecting the first conductive pin and the first support is four or five. In the case that the diameter of the conductive wire is 50 μm, the number of the conductive wires connecting the first conductive pin and the first support is at least 12.

The following introduces the manner of setting the conductive pin and the manner of connecting the light-emitting chip in the laser.

In the embodiments of the present disclosure, the light-emitting chip 104 includes a first electrode, a light-emitting layer, and a second electrode that are sequentially laminated. The first electrode and the second electrode are respectively connected to the positive terminal and the negative terminal of the power supply, such that the light-emitting layer is excited to emit laser light. For example, the first electrode is connected to the positive terminal of the power supply, and the second electrode is connected to the negative terminal of the power supply. Alternatively, the first electrode is connected to the negative terminal of the power supply, and the second electrode is connected to the positive terminal of the power supply. The first electrode, the light-emitting layer, and the second electrode are not illustrated in the embodiments of the present disclosure. The plurality of conductive pins 103 in the laser include positive pins and negative pins, the positive pins are used to be connected to the positive terminal of the power supple, and the negative pins are used to be connected to the negative terminal of the power supple. The first electrode of the light-emitting chip achieves the connection to the positive terminal of the power supple by being connected to the positive pin, and the second electrode of the light-emitting chip achieves the connection to the negative terminal of the power supple by being connected to the negative pin.

In the embodiments of the present disclosure, the plurality of light-emitting chips 104 in the laser are arranged in a plurality of rows and a plurality of columns, at least one row of the plurality of light-emitting chips 104 are cascaded. Two light-emitting chips at the edge of the at least one row of the plurality of cascaded light-emitting chips 104 are the first light-emitting chips. The first electrode of one first light-emitting chip is connected to the positive pin by the first support, and the second electrode of the other first light-emitting chip is connected to the negative pin by the first support, such that the light-emitting chips in the laser are connected to the power supply. In the case that the power supply supplies the current to the positive pin and the negative pin, the plurality of cascaded light-emitting chips 104 of at least one row connected to the two conductive pins are conducted to emit laser light. As shown in FIG. 8, a number of the light-emitting chips in the laser is 16, and the plurality of light-emitting chips are arranged in four rows and four columns, and four light-emitting chips in each row are cascaded. In some embodiments, the number of the light-emitting chips in the laser is 12, 14, 20 or the like, and the light-emitting chips can be arranged in two rows and seven columns or four rows and three columns or in other arrangements, which are not limited in the embodiments of the present disclosure.

In a first manner of cascading the light-emitting chips, a number of rows of the at least one row of the plurality of light-emitting chips is one, that is, the light-emitting chips of each row in the laser are cascaded, and the light-emitting chips of each row are sequentially connected in a row direction. Two light-emitting chips at the two ends of each row of the light-emitting chips are the first light-emitting chips, and the two first light-emitting chips are respectively connected to the positive terminal and negative terminal of the power supple by the first support and the first conductive pin. For example, referring to FIG. 7 and FIG. 8, in each row of the light-emitting chips 104, a first electrode of a first light-emitting chip 104 is connected to the positive pin via the conductive wire and the support 108, a second electrode of a previous light-emitting chip 104 is connected to a first electrode of a next light-emitting chip 104 via the conductive wire, and a second electrode of a last light-emitting chip 104 is connected to the negative pin via the conductive wire and the support 108.

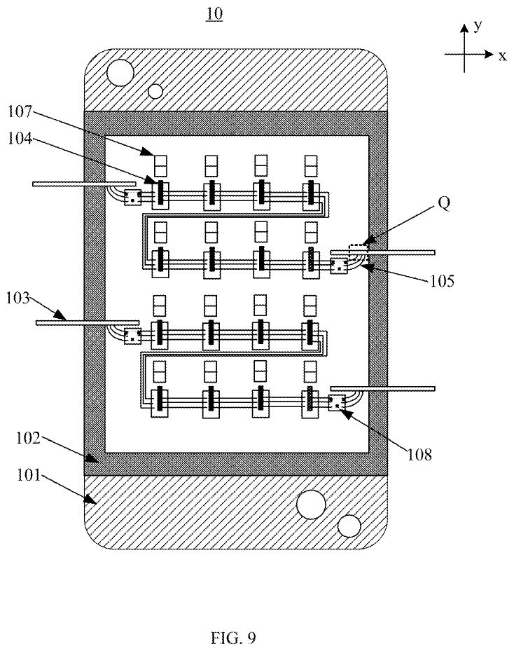

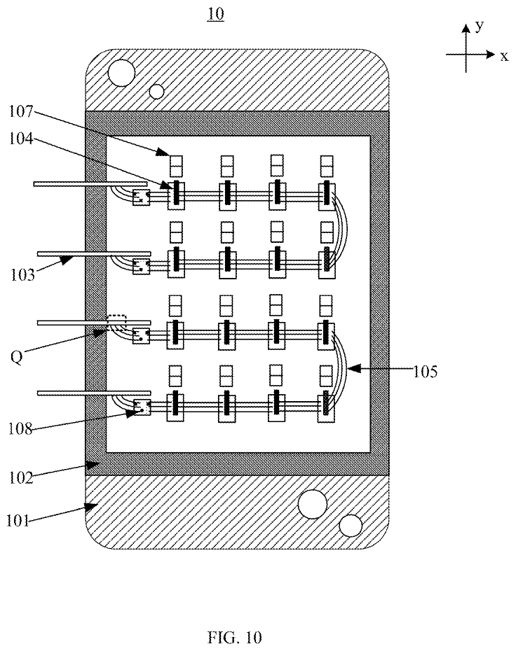

In a second manner of cascading the light-emitting chips, the at least one row of the plurality of light-emitting chips is greater than one row, that is, the light-emitting chips of at least two rows in the laser are cascaded, for example, the light-emitting chips of at least two adjacent rows are cascaded. In the at least two rows of the light-emitting chips, the light-emitting chips of each row are sequentially connected in a row direction, and two light-emitting chips at the same end of the two adjacent rows of the light-emitting chips are connected, or two light-emitting chips at different ends are connected, such that the light-emitting chips of the at least two rows are cascaded. Illustratively, FIG. 9 is a schematic structural diagram of another laser according to some embodiments of the present disclosure, and FIG. 10 is a schematic structural diagram of another laser according to some embodiments of the present disclosure. As shown in FIG. 9 and FIG. 10, the light-emitting chips 104 of each row in the laser are cascaded, and the light-emitting chips 104 of each two adjacent rows are cascaded. The specific manner of cascading the light-emitting chips in each row of the light-emitting chips may refer to the above first cascading manner, which is not repeated in the embodiments of the present disclosure. It should be noted that FIG. 9 and FIG. 10 are illustrated by taking the light-emitting chips in two rows being cascaded as an example, and the light-emitting chips in three or four rows in the laser are cascaded in some embodiments, or all light-emitting chips are cascaded, which is not limited in the embodiments of the present disclosure. In the case that all light-emitting chips are cascaded, the conductive pin in the laser includes one positive pin and one negative pin.

In FIG. 9, in two adjacent rows of the light-emitting chips 104, a last light-emitting chip 104 in a previous row of the light-emitting chips 104 is directly connected to a first light-emitting chip 104 in a next row of the light-emitting chips 104 via the conductive wire. The embodiments of the present disclosure are illustrated by taking a first light-emitting chip and a last light-emitting chip in one row of the light-emitting chips being determined based on an arrangement order of the light-emitting chips in the x direction, that is, a light-emitting chip at the leftmost end of each row of the light-emitting chips being a first light-emitting chip, and a light-emitting chip at the rightmost end of each row of the light-emitting chips being a last light-emitting chip as an example. In FIG. 10, in two adjacent rows of the light-emitting chips 104, a last light-emitting chip 104 in a previous row of the light-emitting chips 104 is connected to a last light-emitting chip 104 in a next row of the light-emitting chips 104.

In some embodiments, for the manner of connecting the adjacent rows of the light-emitting chips in FIG. 9, the last light-emitting chip in the previous row of the light-emitting chips is directly connected to the first light-emitting chip in the next row of the light-emitting chips via the conductive wire. In some embodiments, a conductive structure is predetermined on the base plate between two adjacent rows of the light-emitting chips, and the two light-emitting chips are respectively connected to two ends of the conductive structure to achieve connection of the two light-emitting chips. In some embodiments, a support is disposed on the base plate between two adjacent rows of the light-emitting chips, such that the conductive wire connects the two light-emitting chips by the support, and the less reliability caused by a longer conductive wire in directly connecting two light-emitting chips by the conductive wire is avoided. The support herein can refer to the description of the support between the light-emitting chip and the conductive pin, which is not repeated in the embodiments of the present disclosure.

It should be noted that the light-emitting chips of the plurality of rows in the laser are cascaded only in the above first cascading manner or in the above second cascading manner. In the embodiments of the present disclosure, the light-emitting chips in the laser in FIG. 8 and FIG. 9 are cascaded only in the above first cascading manner, and the light-emitting chips in the laser in FIG. 10 are cascaded only in the above second cascading manner. In some embodiments, a part of the light-emitting chips of the plurality of rows are cascaded in the above first cascading manner, and the remaining light-emitting chips of the plurality of rows of the light-emitting chips are cascaded in the above second cascading manner, which are not limited in the embodiments of the present disclosure. For example, the laser includes four rows of the light-emitting chips, the light-emitting chips of a first two rows in the four rows of the light-emitting chips are cascaded, and the light-emitting chips of a last two rows in the four rows of the light-emitting chips are separately cascaded. For example, the light-emitting chips of the first two rows are used to emit laser light of a first color, the third row of the light-emitting chips are used to emit laser light of a second color, and the fourth row of the light-emitting chips are used to emit laser light of a third color.

In the embodiments of the present disclosure, extension directions of the plurality of conductive pins 103 in the laser are parallel to each other, and are parallel to a row direction of the light-emitting chips (the x direction in FIGS. 5 to 7). In a first manner of affixing the conductive pins, referring to FIGS. 7 to 9, the plurality of conductive pins 103 in the laser are affixed into two opposite sides of the side wall 102, for example, the two opposite sides are two sides of the side wall 102 in the row direction of the light-emitting chips 104. For example, the positive pins and the negative pins in the plurality of conductive pins 103 are respectively affixed into different sides of the side wall, or both the positive pin and the negative pin are affixed into each side of the side wall, which is not limited in the embodiments of the present disclosure. In a second manner of affixing the conductive pins, referring to FIG. 10, the plurality of conductive pins 103 are affixed into one side of the side wall, for example, a target side of the side wall. The target side is any side of two opposite sides of the side wall in the row direction of the light-emitting chips. In some embodiments, the positive pins and the negative pins in the plurality of conductive pins are alternately arranged in the row direction of the light-emitting chips.

It should be noted that the manner of cascading the light-emitting chips in the laser is matched with the manner of affixing the conductive pins. In some embodiments, the positive pins and the negative pins in the laser are respectively affixed into two opposite sides of the side wall, and two first light-emitting chips in the at least one row of cascaded light-emitting chips in the laser are respectively proximal to the two opposite sides. For example, as shown in FIG. 8, the at least one row of the light-emitting chips includes one row of the light-emitting chips. Alternatively, as shown in FIG. 9, the at least one row of the light-emitting chips includes the light-emitting chips of even number rows, and two light-emitting chips at different ends of two adjacent rows of the light-emitting chips in the light-emitting chips of even number rows are connected. Alternatively, the at least one row of the light-emitting chips includes the light-emitting chips of odd number rows, two light-emitting chips at the same end of two adjacent rows of the light-emitting chips in the light-emitting chips of odd number rows are connected, and the connecting manner is the manner of connecting two adjacent rows of the light-emitting chips in FIG. 10. In some embodiments, all pins in the laser are affixed into the target side of the side wall, and two first light-emitting chips in the at least one row of cascaded light-emitting chips in the laser are proximal to the target sides. For example, as shown in FIG. 10, the light-emitting chips of the at least one row include the light-emitting chips of even number rows, and two light-emitting chips at the same end of two adjacent rows of the light-emitting chips in the light-emitting chips of even number rows are connected. Alternatively, the light-emitting chips of the at least one row include the light-emitting chips of odd number rows, two light-emitting chips at different ends of two adjacent rows of the light-emitting chips in the light-emitting chips of odd number rows are connected, and the connecting manner is the manner of connecting two adjacent rows of the light-emitting chips in FIG. 9.

In some embodiments, the laser is a laser of multiple colors, and the light-emitting chips in the laser include light-emitting chips for emitting red laser light, light-emitting chips for emitting green laser light, and light-emitting chips for emitting blue laser light. The light-emitting chips for emitting the laser light of the same color in the laser are cascaded. For example, all the light-emitting chips in the laser are used to emit laser light of the same color and are cascaded, and the conductive pins in the laser merely include one positive pin and one negative pin.

Referring to FIG. 7 to FIG. 10, the laser 10 in the embodiments of the present disclosure further includes a plurality of heat sinks 106. The plurality of heat sinks 106 are in one-to-one correspondence with the plurality of light-emitting chips 104, and each light-emitting chip 104 is affixed on the base plate 101 via the corresponding heat sink 106. In some embodiments, the heat sink 106 is affixed on a side of the first electrode of the light-emitting chip 104, and the first electrode is in contact with a face M2, distal from the base plate 101, of the heat sink 106. The face M2, distal from the base plate 101, of the heat sink 106 is a second conductive face, the first electrode of the light-emitting chip 104 is connected to the second conductive face M2, and the second electrode of the light-emitting chip 104 is connected to another structure through the second conductive face M2. The second electrode of the light-emitting chip 104 may be directly connected to another structure. In some embodiments, the second conductive face is in a rectangular shape, a length of the rectangle is 2 mm, and a width of the rectangle is 1 mm. The length and the width may be of other values, for example, the length is 2.5 mm, and the width is 1.5 mm, which is not limited in the embodiments of the present disclosure.

For example, in the laser in the embodiments of the present disclosure, a first light-emitting chip and a last light-emitting chip in the light-emitting chips 104 of each row are the first light-emitting chips. The first electrode of the first light-emitting chip 104 is a target electrode, and thus the target electrode of the first light-emitting chip 104 is an electrode proximal to the heat sink 106. The second electrode of the last light-emitting chip 104 is a target electrode, and thus the target electrode of the last first light-emitting chip 104 is an electrode distal from the heat sink 106. For the first light-emitting chip 104 in each row of the light-emitting chips, the first electrode of the light-emitting chip 104 is electrically connected to the conductive wire 105 through the second conductive face M2, and the conductive wire 105 is further connected to the first conductive face M1 of the first support 108. For the last light-emitting chip 104 in each row of the light-emitting chips, the second electrode of the light-emitting chip 104 is directly electrically connected to the conductive wire 105, and the conductive wire 105 is also connected to the first conductive face M1 of the first support 108.

In some embodiments, an orthogonal projection of a target line on the base plate 101 is parallel to the extension direction of the first conductive pin 103. The target line is a line between a center of the first conductive face M1 of the first support 108 and a center of the second conductive face M2 of the heat sink 106 corresponding to the first light-emitting chip 104. In the embodiments of the present disclosure, the first conductive face M1 of the first support 108 is connected to the second conductive face M2 of the heat sink 106 or the second electrode of the light-emitting chip 104 via a plurality of conductive wires 105. The plurality of conductive wires 105 are arranged in a second direction (the y direction in FIG. 8), and the second direction is perpendicular to the extension direction of the conductive pin. For example, one ends of the plurality of conductive wires 105 are sequentially affixed on the first conductive face M1 in the second direction, and the other ends of the plurality of conductive wires 105 are sequentially affixed on the second conductive face M2 or the second electrode in the second direction. In the case that a distance between the first support 108 and the heat sink 106 is affixed in the extension direction of the first conductive pin 103, and the line between the center of the first conductive face M1 and the center of the second conductive face M2 is parallel to the extension direction of the first conductive pin 103, a distance between the center of the first conductive face M1 and the center of the second conductive face M2 is minimum. As such, a distance between two ends of the conductive wires connecting the first conductive face and the second conductive face is less, a length of the conductive wire is less, and the reliability of the conductive wire is further improved.

The following introduces the structure of the support in conjunction with the accompanying drawings.

FIG. 11 is a schematic structural diagram of a support according to some embodiments of the present disclosure. As shown in FIG. 11, the support 108 includes a support body 1081 and a conductive layer 1082. The conductive layer 1082 is disposed on a side, distal from the base plate 101, of the support body 1081, and the support body 1081 is made of an insulating material. For example, the conductive layer 1082 is made of gold, or other metals. The material of the support body 1081 includes aluminum nitride, aluminum oxide, or a ceramic material. It should be noted that the base plate is generally made of a conductive material, and the support body is made of the insulating material in the embodiments of the present disclosure to avoid a case that the current cannot be supplied to the light-emitting chip due to the conduction of the second conductive face of the support and the base plate.

In some embodiments, the support 108 further includes a first auxiliary affixing layer 1083. The first auxiliary affixing layer 1083 is disposed between the support body 1081 and the conductive layer 1082. In some embodiments, the support 108 further includes a second auxiliary affixing layer 1084. The second auxiliary affixing layer 1084 is disposed on a side, proximal to the base plate 101, of the support body 1081. For example, the first auxiliary affixing layer 1083 includes a titanium layer and a platinum layer that are laminated, and the platinum layer is in contact with the conductive layer 1082. The second auxiliary affixing layer 1083 includes a titanium layer, a platinum layer, and a gold layer that are laminated, and the titanium layer is in contact with the support body 1081. It should be noted that it is greatly difficult to directly deposit the gold layer on the support body and to directly affix the support body on the base plate. In the embodiments of the present disclosure, a side, distal from the base plate, of the support body is sequentially deposited with a titanium layer and a platinum layer, and a gold layer is further deposited on the platinum layer, such that the affixation of the gold later is endured. Furthermore, in the embodiments of the present disclosure, a side, proximal to the base plate, of the support body is sequentially deposited with a titanium layer, a platinum layer, and a gold layer, and the difficulty of affixing the gold layer and the base plate is less. Therefore, the difficulty of affixing the support on the base plate is reduced, and the affixation of the support is improved.

In some embodiments, the support 108 is in a cylindrical shape, an elliptical shape, a prismatic shape, or other cylindrical shapes. Correspondingly, the first conductive face of the support 108 is in a circular shape, an oval shape, a rectangular shape, or other polygonal shapes. An area of the first conductive face ranges from 0.8 mm² to 1.1 mm². For example, the first conductive face is in a rectangular shape, a width of the rectangle ranges from 0.85 mm to 0.95 mm, and a length of the rectangle ranges from 1.05 mm to 1.15 mm. For example, the length of the rectangle is 1.1 mm, and the width of the rectangle is 0.9 mm. The size of the first conductive face can meet requirements of the conductive wires. In some embodiments, the size of the first conductive face is correspondingly adjusted based on the number and diameter of the conductive wires, which is not limited in the embodiments of the present disclosure. In some embodiments, a length direction of the first conductive face of the support is parallel to a length direction of the second conductive face of the heat sink, and a width direction of the first conductive face is parallel to a width direction of the second conductive face of the heat sink.

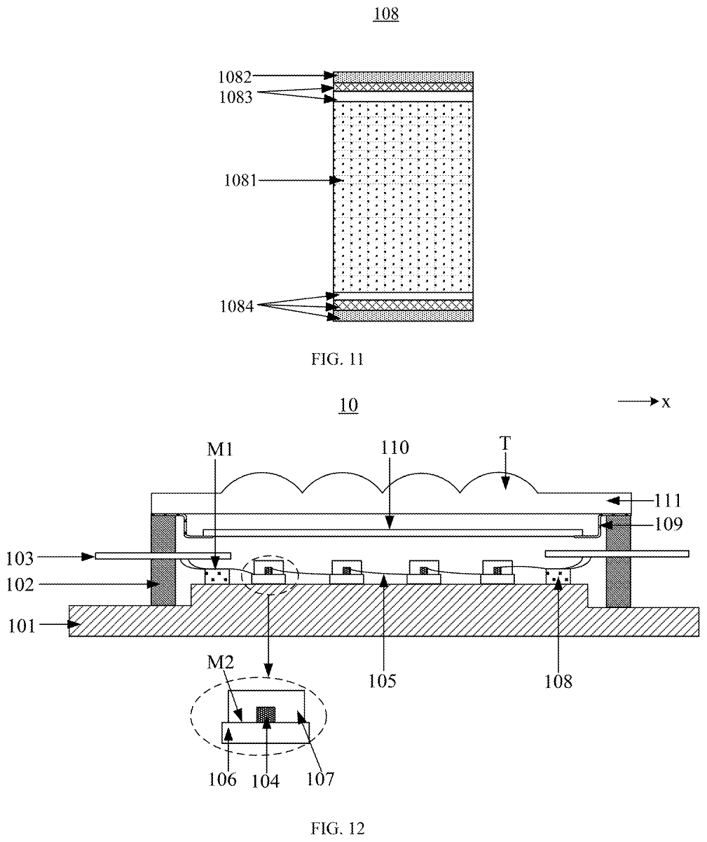

FIG. 12 is a schematic structural diagram of another laser according to some embodiments of the present disclosure. As shown in FIG. 12, the laser further includes a plurality of reflective prisms 107, a seal frame 109, a transparent seal layer 110, and a collimator set 111. The plurality of reflective prisms 107 are all affixed on the base plate 101, and the plurality of reflective prisms 107 are in one-to-one correspondence with the plurality of light-emitting chips 104, and each reflective prism 107 is disposed on a light-emitting side of the corresponding light-emitting chip 104. An outer edge of the seal frame 109 is affixed on a surface of the side wall 102 distal from the base plate 101, a side of an inner edge of the seal frame 109 distal from the base plate 101 is affixed on the transparent seal layer 110, and the collimator set 111 is disposed on a side of the seal frame 109 distal from the base plate 101. The collimator set 111 includes a plurality of collimating lenses T, and the plurality of collimating lenses T are in one-to-one correspondence with the plurality of light-emitting chips 104. Each light-emitting chip 104 emits the laser light to the corresponding reflective prism 107, the laser light travels through the transparent seal layer 110 upon being reflected by the reflective prism 107 and then directs to the corresponding collimating lens T, and then the laser is transmitted upon being collimated by the collimating lens T, such that the laser emits the light.

In the embodiments of the present disclosure, the housing is made of copper, for example, oxygen-free copper, the transparent seal layer is made of glass, and a seal cover plate is made of stainless steel. It should be noted that a heat transfer coefficient of copper is great, and the housing is made of copper in the embodiments of the present disclosure, such that the heat generated by the operation of the light-emitting chip on the base plate of the housing can be quickly transferred through the housing and then be quickly dissipated, and the damage on the light-emitting chip caused by heat accumulation is avoided. In some embodiments, the housing is made of one or more of aluminum, aluminum nitride, and silicon carbide. In the embodiments of the present disclosure, the seal cover plate may be made of other Kovar materials, for example, an iron nickel cobalt alloy or other alloys. The transparent seal layer may be made of other transparent material with great reliability, for example, a resin material or the like.

In the embodiments of the present disclosure, in assembling the laser, an annular solder structure (for example, an annular glass bead) is disposed in the opening in the side wall of the housing, and the conductive pin is extended through the solder structure and the opening of the solder structure. Then, the side wall is placed on a bottom face of the base plate, an annular silver copper solder is placed between the base plate and the side wall, structures of the base plate, the side wall, and the conductive pin are placed in a high temperature furnace for seal sinter, and the base plate, the side wall, the conductive pin, and the solder are an integrated structure upon the seal sinter and curing, such that air tightness at the opening of the side wall is achieved. The transparent seal layer and the seal frame are affixed, for example, an edge of the transparent seal layer is attached to an inner edge of the seal frame, such that a seal assembly is acquired. Then, a combined member of the light-emitting chip and the heat sink, the support, and the reflective prism are welded on the base plate, and the gold wire is disposed between the conductive pin and the support, between the support and the heat sink, and between the support and the second electrode the light-emitting chip. Then, the seal assembly is welded on the side wall by a parallel sealing welding technology, the collimator set is affixed on a side, distal from the base plate, of the seal assembly, and the assembling of laser is completed. It should be noted that the above assembling process is merely an illustrative process in the embodiments of the present disclosure, the welding process in the processes can be replaced by other process, and the order of the processes can be adeptly adjusted, which are not limited in the embodiments of the present disclosure.

It should be noted that the above embodiments of the present disclosure are illustrated by taking the base plate and the side wall of the housing being assembled as two separate structures as an example. In some embodiments, the base plate and the side wall are of an integrated structure. As such, wrinkles of the base plate caused by the different coefficients of thermal expansion of the base plate and the side wall in high temperature welding are avoided, such that the flatness of the base plate is ensured, the reliability of disposing the light-emitting chip on the base plate is ensured, emission of the light emitted by the light-emitting chip at a predetermined light-emitting angle is ensured, and the luminous effect of the laser is improved.

In summary, in the laser in the embodiments of the present disclosure, the electric connection of the conductive pin and the target electrode of the light-emitting chip is changed over through the support. The support is disposed between the conductive pin and the light-emitting chip, and a height of the support is between the height of the wiring region of the conductive pin and the height of the target electrode of the light-emitting chip. Thus, the conductive wire connecting the conductive pin and the support is shorter, the conductive wire connecting the support and the target electrode of the light-emitting chip is shorter, and the difference in height of two objects connected by each conductive wire is less. Thus, the reliability of the conductive wire is great, and thus the reliability of the laser is improved.

It should be noted that in the present disclosure, the term “and/or” is merely an associated relationship of the associated objects, and indicates that there may be three relationships. For example, A and/or B may indicate that there are three cases where A exists separately, A and B exist simultaneously, and B exists separately. In addition, the symbol “/” herein refers to an “or” relationship of the associated objects. The terms “first” and “second” are only used for the purpose of description and should not be construed as indicating or implying relative importance. Unless otherwise clearly defined, the expression “a plurality of” refers to two or more. The term “almost” refers that within an acceptable error range, and those skilled in the art can solve the technical problem within an error range and basically achieve the technical effect. It should be noted that in the accompanying drawings, for clarity of the illustration, the dimension of the layers and regions may be scaled up. It should be understood that when an element or layer is described as being “on” another element or layer, the described element or layer may be directly located on other elements or layers, or an intermediate layer may exist. In the whole disclosure, like reference numerals indicate like elements.

Described above are merely exemplary embodiments of the present disclosure, and are not intended to limit the present disclosure. Any modifications, equivalent replacements, improvements and the like made within the spirit and principles of the present disclosure should be encompassed within the scope of protection of the present disclosure.

What is claimed is:

1. A laser, comprising:
a base plate, an annular side wall, a plurality of conductive pins, a plurality of light-emitting chips, and a plurality of conductive wires;
wherein the side wall and the plurality of light-emitting chips are disposed on the base plate, the side wall surrounds the plurality of light-emitting chips, the plurality of conductive pins are extended through the side wall and are affixed into the side wall, and sides, distal from the base plate, of portions of the plurality of conductive pins surrounded by the side wall comprise planar regions,
wherein the planar region of each of the plurality of conductive pins is connected to the light-emitting chip via the conductive wire.

2. The laser according to claim 1, wherein the planar region is disposed at an end, distal from the side wall, of the portion of the conductive pin surrounded by the side wall.

3. The laser according to claim 1, wherein sides, proximal to the base plate, of the portions of the plurality of conductive pins surrounded by the side wall comprise planar regions.

4. The laser according to claim 1, wherein a boundary of the planar region defines a rectangle, wherein a length direction of the rectangle is parallel to an extension direction of the conductive pin.

5. The laser according to claim 1, wherein
the plurality of light-emitting chips are arranged in a plurality of rows and a plurality of columns, the plurality of conductive pins comprise positive pins and negative pins; and
the plurality of light-emitting chips and the plurality of conductive pins meet conditions that:
the positive pins and the negative pins are respectively affixed into two opposite sides of the side wall in a row direction of the plurality of light-emitting chips, at least one row of the plurality of light-emitting chips are cascaded, and two first light-emitting chips in the at least one row of the plurality of light-emitting chips are respective proximal to the two opposite sides of the side wall; or
the plurality of conductive pins are affixed into a target side of the side wall, at least two rows of the plurality of light-emitting chips are cascaded, two first light-emitting chips in the at least two rows of the plurality of light-emitting chips are in different rows and are proximal to the target side of the side wall.

6. The laser according to claim 1, further comprising: a plurality of supports affixed on the base plate, wherein each of the plurality of conductive pins corresponds to one of the plurality of supports, and a first conductive face of each of the plurality of supports is connected to a wiring region of the corresponding conductive pin and a target electrode of the light-emitting chip via the conductive wires.

7. The laser according to claim 6, wherein
the first conductive face of the support is a surface, distal from the base plate, of the support;
in an extension direction of a first conductive pin of the plurality of conductive pins, a first support is disposed between a wiring region of the first conductive pin and a first light-emitting chip of the plurality of light-emitting chips, and a height of the wiring region of the first conductive pin relative to the base plate, a height of a first conductive face of the first support relative to the base plate, and a height of a target electrode of the first light-emitting chip relative to the base plate are sequentially decreased; and
the first conductive pin is any one of the plurality of conductive pins, and the first conductive pin is connected to the first light-emitting chip by the first support.

8. The laser according to claim 6, wherein in an extension direction of a first conductive pin of the plurality of conductive chips, a distance between an end, proximal to a first light-emitting chip of the plurality of light-emitting chips, of the first conductive pin and an end, proximal to the first light-emitting chip, of a first support is less than a distance threshold.

9. The laser according to claim 6, further comprising: a plurality of heat sinks, wherein the plurality of heat sinks are in one-to-one correspondence with the plurality of light-emitting chips, and the light-emitting chip is affixed on the base plate via the corresponding heat sink, wherein a surface, distal from the base plate, of the heat sink is a second conductive face, and for a first light-emitting chip of which a target electrode is proximal to the heat sink, the target electrode of the first light-emitting chip is electronically connected to the conductive wire via the second conductive face.

10. The laser according to claim 6, wherein the support comprises a support body and a conductive layer, wherein the conductive layer is disposed on a side, distal from the base plate, of the support body, and the support body is made of an insulating material.

11. The laser according to claim 10, wherein
the support further comprises a first auxiliary affixing layer, wherein the first auxiliary affixing layer is disposed between the support body and the conductive layer; and/or
the support further comprises a second auxiliary affixing layer, wherein the second auxiliary affixing layer is disposed on a side, proximal to the base plate, of the support body.

12. The laser according to claim 1, wherein
a length of the planar region in an extension direction of the conductive pin ranges from 2 mm to 3 mm; and/or
a length of the planar region in a direction perpendicular to the extension direction of the conductive pin ranges from 1 mm to 2 mm.

13. The laser according to claim 1, wherein
in the extension direction of the conductive pin, a length of the portion of the conductive pin surrounded by the side wall ranges from 3 mm to 3.5 mm; and/or
a length of the conductive pin ranges from 8 mm to 10 mm.

14. The laser according to claim 1, wherein another portion of the conductive pin is in a cylindrical shape, and an orthogonal projection of the another portion on the base plate is disposed beyond an orthogonal projection of the planar region on the base plate.

15. The laser according to claim 6, wherein the support meets at least one of conditions that:
a distance between the first conductive face and the base plate ranges from 0.3 mm to 0.4 mm; and
an area of the first conductive face ranges from 0.8 mm² to 1.1 mm².

16. A laser, comprising:
a base plate, an annular side wall, a plurality of conductive pins, a plurality of light-emitting chips, a plurality of conductive wires, and a plurality of supports;
wherein the side wall and the plurality of light-emitting chips are disposed on the base plate, the side wall surrounds the plurality of light-emitting chips, the plurality of conductive pins are extended through the side wall and are affixed into the side wall, the plurality of supports are affixed on the base plate, and each of the plurality of conductive pins corresponds to one of the plurality of supports, and a first conductive face of each of the plurality of supports is connected to a wiring region of the corresponding conductive pin and a target electrode of the light-emitting chip via the conductive wires.

17. The laser according to claim 16, wherein sides, distal from the base plate, of portions of the plurality of conductive pins surrounded by the side wall comprise planar regions, wherein the planar region of each of the plurality of conductive pins is connected to the light-emitting chip via the conductive wire.

18. The laser according to claim 17, wherein in the case that the laser is a laser of a single color, the plurality of light-emitting chips are arranged in N rows, and both a number of the supports and a number of the planar regions are 2N, N being an integer greater than or equal to 1.

19. The laser according to claim 17, wherein in the case that the laser is a laser of three colors, the plurality of light-emitting chips are arranged in N rows, colors of laser light emitted by the light-emitting chips arranged in each of the N rows are the same, and both a number of the supports and a number of the planar regions are 2N, N being a multiple of 4.

20. The laser according to claim 17, wherein in the case that the laser is a laser of three colors, the plurality of light-emitting chips are arranged in N rows, the light-emitting chips of at least one of the N rows comprise light-emitting chips for emitting laser light of two colors, a number of the supports is 3N, N being a multiple of 2.
